(19) United States
(12) Patent Application Publication
(10) Pub. No.: US 2011/0248322 A1
(43) Pub. Date: Oct. 13, 2011

(54) Piezoelectric Gate-Induced Strain

(75) Inventors: King-Yuen Wong, Hsin-Chu (TW); Chien-Tai Chan, Hsin-Chu (TW); Da-Wen Lin, Hsin-Chu (TW); Chung-Cheng Wu, Chu-Bei City (TW)

(73) Assignee: Taiwan Semiconductor Manufacturing Company, Ltd., Hsin-Chu (TW)

(21) Appl. No.: 12/758,568

(22) Filed: Apr. 12, 2010

(51) Int. Cl. H01L 29/78; H01L 21/336

(52) U.S. Cl. 257/288; 438/299; 257/E21.409; 257/E29.255

(57) ABSTRACT

An embodiment is a semiconductor device. The semiconductor device comprises a substrate, an electrode over the substrate, and a piezoelectric layer disposed between the substrate and the electrode. The piezoelectric layer causes a strain in the substrate when an electric field is generated by the electrode.

### TECHNICAL FIELD

The present disclosure relates generally to a semiconductor device and method of manufacture and, more particularly, to a transistor structure comprising a piezoelectric material in a gate stack and a method of manufacture and of operation.

### BACKGROUND

Generally, it is known that stress is desirable in a transistor channel to improve carrier mobility, and thus, to improve a drive current in the transistor. An increased drive current may increase the operational speed of the transistor. Stress may be compressive or tensile. Stress may also be defined by the direction in which it is applied. A biaxial stress is generally defined to be stress within a plane of a surface of a channel of a transistor, with stress being applied in a direction parallel to the width of the channel and a stress being applied to a direction parallel to the length of the channel. A third direction of stress may be in a direction orthogonal to the plane of the surface of the channel.

It is also generally known that a stress may affect different channel type transistors differently. For example, a compressive stress in a direction parallel to the length of a channel is generally desirable for a p-channel transistor, but a biaxial tensile stress is generally desirable for an n-channel transistor. However, a biaxial compressive stress may degrade the performance of an n-channel transistor, and a biaxial tensile stress may degrade the performance of a p-channel transistor. Further, a tensile stress in the direction orthogonal to the plane of the surface of the channel may be desirable for a p-channel transistor, and a compressive stress in that direction may be desirable for an n-channel transistor.

Methods are known for applying stresses and strains to transistors, but these methods may have disadvantages. One method, for example, includes forming a compressive polysilicon gate electrode within a gate stack which causes a tensile stress in the channel underlying the gate stack. However, using this method, the stress is fixed upon formation of the device and may not be changed during the operation of the device. The fixed stress may not always be desirable. For example, one may want a transistor to have a high tensile stress during the transistor's “on” state to increase carrier mobility, but may want the transistor to have a low tensile stress during an “off” state to decrease leakage current. Thus, what is needed in the art is a device and method for tuning the strain in a channel for different operations.

### SUMMARY

In accordance with an embodiment, a semiconductor device comprises a substrate, an electrode over the substrate, and a piezoelectric layer disposed between the substrate and the electrode. The piezoelectric layer causes a strain in the substrate when an electric field is generated by the electrode.

In accordance with another embodiment, a semiconductor device comprises a gate stack comprising a gate electrode over a substrate, and a piezoelectric layer between the gate electrode and the substrate. The semiconductor device further comprises source/drain regions oppositely disposed adjacent the gate stack in the substrate. The source/drain regions define a channel region in the substrate underlying the gate stack. The piezoelectric layer alters a strain in the channel region corresponding to an electric field being altered that is generated by the gate electrode.

In accordance with a further embodiment, a method for forming a semiconductor device comprises providing a substrate, forming a piezoelectric layer over the substrate, forming an electrode layer over the piezoelectric layer, and patterning the piezoelectric layer and the electrode layer into a gate stack.

In accordance with a yet further embodiment, a method for operating a semiconductor device comprises increasing an electric field to a piezoelectric material in a gate stack, thereby changing a strain in a region in a substrate underlying the gate stack, and decreasing the electric field to the piezoelectric material in the gate stack, thereby changing the strain in the region in a substrate underlying the gate stack.

### BRIEF DESCRIPTION OF THE DRAWINGS

For a more complete understanding of the disclosure, and the advantages thereof, reference is now made to the following descriptions taken in conjunction with the accompanying drawings, in which:

FIG. 1 is a planar transistor according to an embodiment;

FIG. 2 is a planar transistor according to another embodiment;

FIG. 3 is an example of dipoles and the reverse piezoelectric effect;

FIGS. 4A-4D are examples of resulting stresses in embodiments;

FIG. 5 is a method for operating a transistor with a piezoelectric layer in a gate stack according to an embodiment;

FIG. 6 is a flowchart of a manufacturing process to form a structure of an embodiment according to an embodiment; and

FIGS. 7A-7C are fin field effect transistors (finFETs) according to other embodiments.

### DETAILED DESCRIPTION OF ILLUSTRATIVE EMBODIMENTS

The making and using of the embodiments are discussed in detail below. It should be appreciated, however, that the disclosure provides many applicable concepts that can be embodied in a wide variety of specific contexts. The specific embodiments discussed are merely illustrative, and do not limit the scope of the disclosure.

Some embodiments are discussed in detail in a specific context, namely a planar transistor. However, other embodiments may be used in conjunction with other devices, such as fin field effect transistors (finFETs).

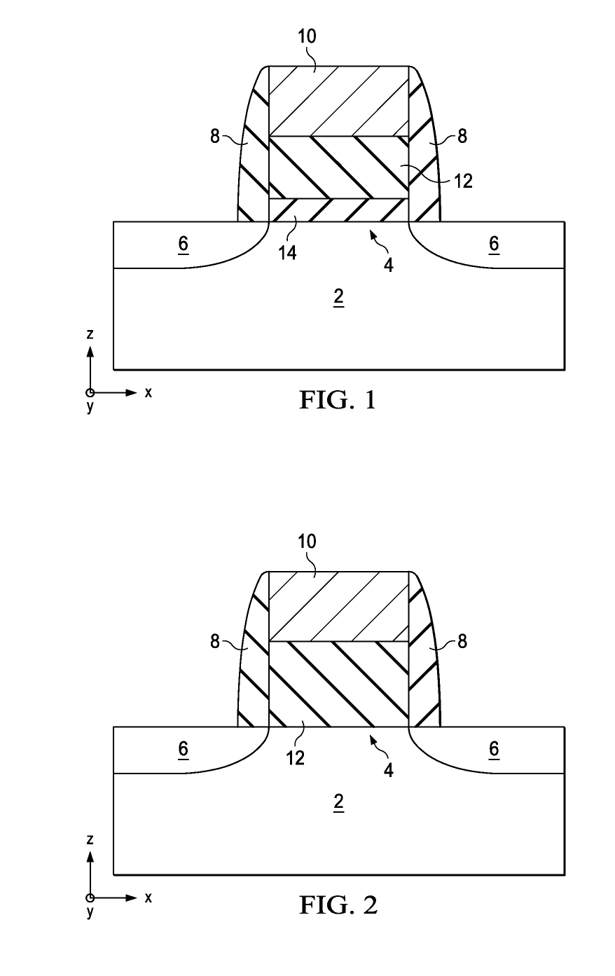

FIG. 1 illustrates a planar transistor according to an embodiment. The transistor includes a substrate 2, source/drain regions 6 in the substrate 2, a channel region 4 in the substrate 2 disposed between the source/drain regions 6, and a gate stack on the substrate 2. The gate stack includes a gate dielectric 14 over and adjoining the substrate 2, a piezoelectric layer 12 over and adjoining the gate dielectric 14, a gate electrode 10 over and adjoining the piezoelectric layer 12, and a dielectric spacer 8 along sidewalls of the gate dielectric 14, the piezoelectric layer 12, and the gate electrode 10.

The substrate 2 may be silicon, silicon germanium, germanium, silicon carbide, gallium arsenide, and the like. The substrate 2 may further be a bulk material, semiconductor on insulator (SOI), or the like. Further, the substrate 2 may be doped oppositely from the conductivity type of the transistor by, for example, phosphorous, arsenic, boron, or the like, depending on the substrate 2 material. Source/drain regions 6 may be doped according to the conductivity type of the transistor, such as by phosphorous, arsenic, boron, or the like, and may utilize any suitable doping profile.

The gate dielectric 14 may be an oxide, nitride, oxynitride, or other materials known in the art. The gate electrode 10 may be amorphous silicon, polysilicon, metal, metal silicide, metal nitride, combinations thereof, or other known materials. The gate electrode 10 may further comprise a tensile or compressive stress. Dielectric spacer 8 may be an oxide, nitride, oxynitride, or other material known in the art. The piezoelectric layer 12 may be zinc oxide (ZnO), lithium niobate (LiNbO₃), lithium tantalate (LiTaO₃), or the like. Further, the piezoelectric layer 12 may be any thickness but is more efficient at smaller thicknesses, such as in the nanometer order, i.e. less than 10 nanometers.

FIG. 2 depicts a planar transistor according to another embodiment. The transistor depicted in FIG. 2 is similar to that shown in FIG. 1, wherein like reference numerals refer to like elements, except the transistor in FIG. 2 does not contain a gate dielectric 14. Depending on the material used for the piezoelectric layer 12, a gate dielectric 14 may be omitted from the structure. Some piezoelectric materials may have a sufficiently high dielectric constant such that the gate dielectric 14 may be a superfluous component of the structure.

FIGS. 1 and 2 illustrate axes that are used for reference throughout this disclosure. The x-direction is a direction parallel to the channel 4 length, and is also called the “1” direction. The y-direction is a direction parallel to the channel 4 width, and is also called the “2” direction. The z-direction is a direction orthogonal to the surface of the substrate 2, and is also called the “3” direction.

The piezoelectric layer 12 takes advantage of the reverse piezoelectric effect. Using the reverse piezoelectric effect, the crystalline structure of the piezoelectric layer 12 may deform, i.e., expand or contract, depending on an electric field applied by the gate electrode 10 such that the deformation may cause a strain in the channel 4 of the transistor. When an electric field is applied to the piezoelectric layer 12, ions that compose dipoles in the piezoelectric layer 12 may expand away from each other or may contract towards each other according to the electric field.

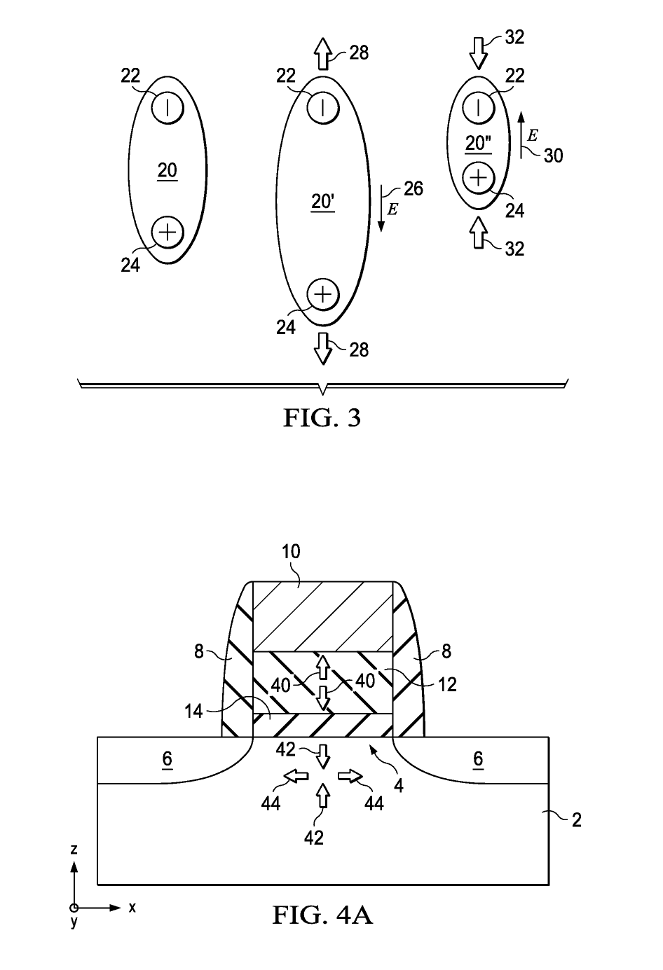

FIG. 3 illustrates an example of dipoles and the reverse piezoelectric effect. FIG. 3 shows dipoles 20, 20′, and 20″. Each of the dipoles comprises a negative ion 22 and a positive ion 24. Dipole 20 depicts the distance between the ions in the crystalline structure when no electric field is applied. Dipole 20′ depicts the distance between the ions when a positive electric field 26 is applied in the direction from the negative ion 22 to the positive ion 24. The electric field 26 thus attracts the negative ion 22 and repels the positive ion 24 such that a tensile stress is applied in the dipole 20′, as indicated by arrows 28. Dipole 20″ depicts the distance between the ions when a positive electric field 30 is applied in the direction from the positive ion 24 to the negative ion 22. The electric field 30 attracts the positive ion 24 and repels the negative ion 22 such that a compressive stress is applied in the dipole 20″, as indicated by arrows 32.

As applied to the transistors depicted in FIGS. 1 and 2, the reverse piezoelectric effect can be used to cause a change in the strain in the channel 4. For example, when the voltage applied to the gate electrode 10 increases, such as higher than the threshold voltage, the piezoelectric layer 12 may expand causing a tensile stress in the z-direction, or in other words, in the direction of the electric field, within the piezoelectric layer 12 but causing a compressive strain in the same direction within the channel 4 of the transistor. The compressive strain in this direction in the channel 4 in turn causes an in-plane biaxial tensile strain, i.e. in the x and y-directions, in the channel 4. Thus, when the gate voltage is at an increased level which causes the strain in the channel 4, the carrier mobility may be increased thereby increasing the drive current of the transistor. However, when the gate voltage is reduced, such as below the threshold voltage, the piezoelectric layer 12 may return to a more relaxed state thereby relieving strain in the channel 4. With strain in the channel 4 relieved, the carrier mobility is reduced, and the diffusion coefficient is reduced, thereby reducing drain leakage current. It is worth noting that the channel 4 may be completely relaxed when the electric field from the gate electrode 10 is removed, but as used herein, the channel 4 may be relaxed even though some strain may still exist because the gate electrode 10 may have a floating potential when the voltage is removed such that the coupling electric field of the gate electrode 10 may induce some strain in the channel 4 or because of a fixed strain formed in the channel 4. The stresses and strains are explained in more detail as follows.

The stress induced in the piezoelectric layer 12 may be explained by the following equation:

[T]=[c][S]−[e][E] Eq. 1

In equation 1, [T] is the stress tensor, [S] is the strain tensor, [c] is the stiffness tensor, [e] is the piezoelectric constant, and [E] is the electric field. In the application to FIG. 1, the strain tensor S and the stiffness tensor c may be omitted as negligible. Thus, equation 1 may be reduced to a simpler form, as shown by equation 2, which shows the entries of each respective matrix.

$$[ \begin{matrix}{T}_{1} \\ {T}_{2} \\ {T}_{3} \\ {T}_{4 } \\ {T}_{5} \\ {T}_{6}\end{matrix} ] = - [ \begin{matrix}{e}_{11} & {e}_{21} & {e}_{31} \\ {e}_{12} & {e}_{22} & {e}_{32} \\ {e}_{13} & {e}_{23} & {e}_{33} \\ {e}_{14} & {e}_{24} & {e}_{34} \\ {e}_{15} & {e}_{25} & {e}_{35} \\ {e}_{16} & {e}_{26} & {e}_{36}\end{matrix} ] [ \begin{matrix}{E}_{1} \\ {E}_{2} \\ {E}_{3}\end{matrix} ] \qquad Eq . 2$$

It is worth noting the directions of the stress entries in the stress tensor [T] are well known in the art, but with respect to FIG. 1, subscript 1 is the x-direction, subscript 2 is the y-direction, and subscript 3 is the z-direction. Subscript 4 indicates a shear stress along the y-z plane (subscripts 23), subscript 5 indicates a shear stress along the x-z plane (subscripts 13), and subscript 6 indicates a shear stress along the x-y plane (subscripts 12).

As a person having ordinary skill in the art would readily understand, the electric field created when a voltage is applied to the gate electrode 10 is substantially only in the z-direction. Thus, the electric field in the x and y-directions may be approximately zero. Accordingly, the electric field matrix [E] may be as follows:

$$[ E ] = [ \begin{matrix}0 \\ 0 \\ {E}_{3}\end{matrix} ] \qquad Eq . 3$$

Further, the e₁ⱼ and e₂ⱼ entries in the piezoelectric constant matrix [e] may be ignored because the entries will only be multiplied by zero from the electric field matrix [E]. With this in mind, equation 2 may be further reduced as show below.

$$[ \begin{matrix}{T}_{1} \\ {T}_{2} \\ {T}_{3} \\ {T}_{4} \\ {T}_{5} \\ {T}_{6}\end{matrix} ] = - [ \begin{matrix}{e}_{31} {E}_{3} \\ {e}_{32} {E}_{3} \\ {e}_{33} {E}_{3} \\ {e}_{34} {E}_{3} \\ {e}_{35} {E}_{3} \\ {e}_{26} {E}_{3}\end{matrix} ] \qquad Eq . 4$$

Table 1, below, shows piezoelectric constants eᵢⱼ for exemplary materials for the piezoelectric layer 12.

TABLE 1

| Piezoelectric | | | |
|---|---|---|---|
| Constants (C/m²) | ZnO | LiNbO₃ | LiTaO₃ |
| e₁₅ | −0.480 | 3.76 | 2.72 |
| e₃₁, e₃₂ | −0.573 | 0.23 | −0.38 |
| e₃₃ | 1.321 | 1.33 | 1.09 |

All other entries of the piezoelectric constant matrix [e] are zero. Thus, equation 4 may be even further reduced as shown below.

$$[ \begin{matrix}{T}_{1} \\ {T}_{2} \\ {T}_{3} \\ {T}_{4} \\ {T}_{5} \\ {T}_{6}\end{matrix} ] = - [ \begin{matrix}{e}_{31} {E}_{3} \\ {e}_{32} {E}_{3} \\ {e}_{33} {E}_{3} \\ 0 \\ 0 \\ 0\end{matrix} ] \qquad Eq . 5$$

Accordingly, the resultant stress in the piezoelectric layer 12 may be substantially in the x-direction, the y-direction, and the z-direction, as indicated in FIG. 1. A positive stress tensor entry Tₖ indicates a tensile stress in the piezoelectric material, whereas a negative stress tensor entry Tₖ indicates a compressive stress in the piezoelectric material.

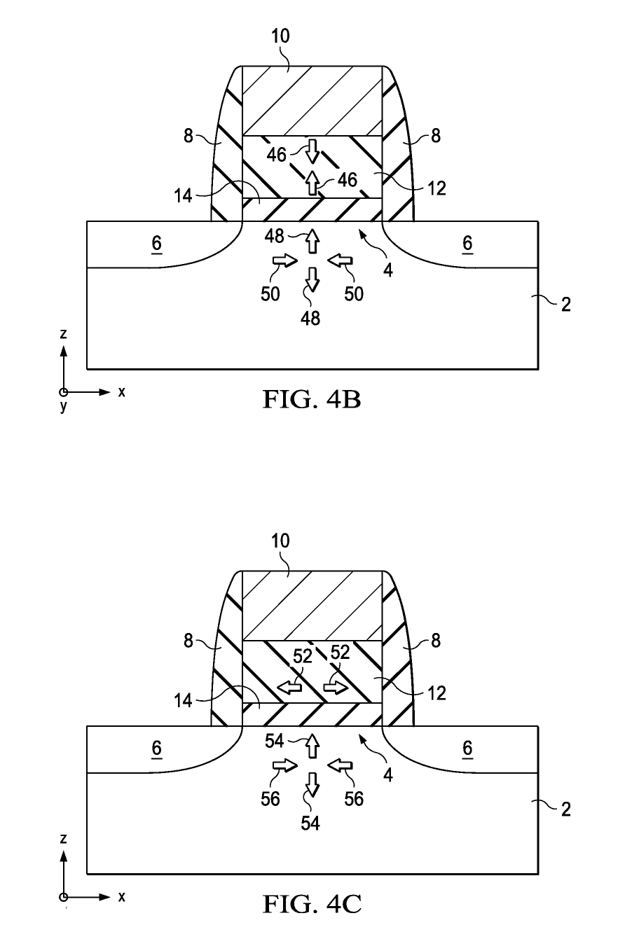

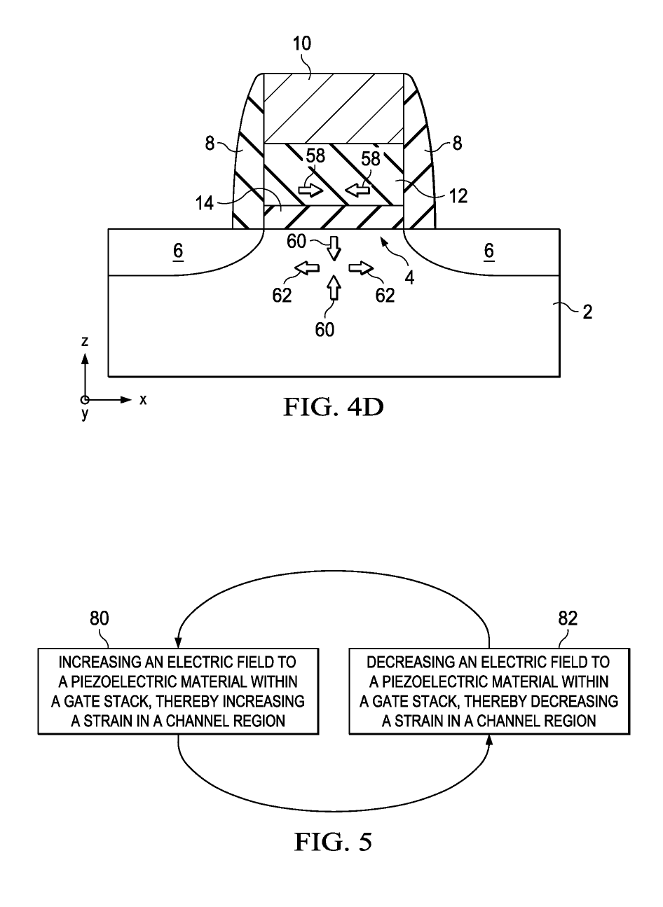

Stresses in the piezoelectric layer 12 may cause strains in the channel 4 in the substrate 2. A stress in one direction in the piezoelectric layer 12 may cause strains in all three directions in the channel 4. FIGS. 4A-4D illustrate examples of these stresses and strains. FIG. 4A shows a tensile stress 40 in the z-direction in the piezoelectric layer 12, i.e. a positive T₃ stress. This stress 40 mechanically causes a compressive strain 42 in the z-direction in the channel 4, which in turn, causes a biaxial tensile strain in the x-direction 44 and in the y-direction (not shown). FIG. 4B shows a compressive stress 46 in the z-direction in the piezoelectric layer 12, i.e. a negative T₃ stress. This compressive stress 46 mechanically causes a tensile strain 48 in the z-direction in the channel 4, which in turn causes a biaxial compressive strain in the x-direction 50 and in the y-direction (not shown).

FIG. 4C illustrates a tensile stress 52 in the x-direction in the piezoelectric layer 12, i.e. a positive T₁ stress. The tensile stress 52 causes a compressive strain 56 in the x-direction in the channel 4. The compressive strain 56 causes a tensile strain in the z-direction 54 and in the y-direction (not shown). FIG. 4D illustrates a compressive stress 58 in the x-direction in the piezoelectric layer 12, i.e. a negative T₁ stress. The compressive stress 58 causes a tensile strain 62 in the x-direction in the channel 4. The tensile strain 62 causes a compressive strain in the z-direction 60 and in the y-direction (not shown). Note that in when a stress is created in the x-direction in the piezoelectric layer 12, the opposite strain is caused in the channel 4 in the x-direction.

Although not illustrated, stresses in the y-direction in the piezoelectric layer 12 have similar effects as stresses in the x-direction in the piezoelectric layer 12. A tensile stress in the y-direction in the piezoelectric layer 12, i.e. a positive T₂ stress, causes a compressive strain in the y-direction in the channel 4. The compressive strain in the y-direction in the channel 4 causes a tensile strain in the z-direction and in the x-direction in the channel 4. A compressive stress in the y-direction in the piezoelectric layer 12, i.e. a negative T₂ stress, causes a tensile strain in the y-direction in the channel 4. The tensile strain in the y-direction in the channel 4 causes a compressive strain in the z-direction and in the x-direction in the channel 4. Like with stresses in the x-direction, note that in when a stress is created in the y-direction in the piezoelectric layer 12, the opposite strain is caused in the channel 4 in the y-direction.

At this point, two examples may be helpful in understanding the operation of the structures in FIGS. 1 and 2. For a first example, assume that the voltage drop across the piezoelectric layer 12 is 1 V, and the thickness Z_{Piezo} of the piezoelectric layer 12 is in the nanometer order, e.g. 1 nm. Further, assume that the piezoelectric material is zinc oxide with e₃₁=e₃₂=−0.573 and e₃₃=1.321. Using the equation

$${E}_{3} = - \frac{\partial V}{\partial z} \approx - \frac{Δ V}{Δ z} = - \frac{{V}_{Piezo}}{{Z}_{Piezo}} ,$$

the electric field E₃ in the z-direction may be calculated to be approximately −1×10⁹ N/C. Thus, the stresses in the piezoelectric layer 12 in the x-direction and y-direction, i.e. T₁ and T₂, respectively, are approximately −5.73×10⁸ N/m², and the stress in the piezoelectric layer 12 in the z-direction, i.e. T₃, is approximately 1.321×10⁹ N/m². This indicates that the x-direction stress in the piezoelectric layer 12 is compressive, like in FIG. 4D, that the y-direction stress in the piezoelectric layer 12 is compressive, and that the z-direction stress is tensile, like in FIG. 4A. The complex interaction of these stresses result in a tensile strain in each of the x-direction and y-direction in the channel 4 and a compressive strain in the z-direction in the channel 4. These resultant strains may enhance the operability of an n-channel field effect transistor (NFET).

For a second example, assume the same assumptions as above with the first example except that voltage drop across the piezoelectric layer is −1 V. Using similar calculations as above, the electric field E₃ in the z-direction may be calculated to be approximately 1×10⁹ N/C. Thus, the stresses in the piezoelectric layer 12 in the x-direction and y-direction, i.e. T₁ and T₂, respectively, are approximately 5.73×10⁸ N/m², and the stress in the piezoelectric layer 12 in the z-direction, i.e. T₃, is approximately −1.321×10⁹ N/m². This indicates that the x-direction stress in the piezoelectric layer 12 is tensile, like in FIG. 4C, that the y-direction stress in the piezoelectric layer 12 is tensile, and that the z-direction stress is compressive, like in FIG. 4B. The complex interaction of these stresses result in a compressive strain in each of the x-direction and y-direction in the channel 4 and a tensile strain in the z-direction in the channel 4. These resultant strains may enhance the operability of a p-channel field effect transistor (PFET).

Although not specifically discussed herein, materials with different piezoelectric constants may be used in different embodiments. For example, by changing the crystal orientation or cut of one of the specific materials cited above, piezoelectric constant e₃₃ may become negative. This feature may be desirable in other semiconductor systems.

As can be inferred from the above discussion, the stress in the piezoelectric layer 12, and thus, the strain in the channel 4, may be modulated by changing the voltage applied to gate electrode 10. As incidentally discussed above, the electric field around the piezoelectric layer 12 may be generated by the voltage applied to the gate electrode 10, and the electric field may be described by

$${E}_{3} = - \frac{\partial V}{\partial z} ,$$

which may be approximated by

$${E}_{3} \approx - \frac{{V}_{Piezo}}{{Z}_{Piezo} }$$

where V_{Piezo} is the voltage drop across the piezoelectric layer 12, and Z_{Piezo} is the thickness of the piezoelectric layer in the z-direction. Thus, the electric field may be modulated by increasing or decreasing the voltage drop across the piezoelectric layer 12, which may in turn alter the stress in the piezoelectric layer 12. The altered stress in the piezoelectric layer 12 may then change the strain resulting in the channel 4.

FIG. 5 depicts a general method for operating a transistor with a piezoelectric layer in a gate stack according to an embodiment. For clarity, “increasing” refers to increasing a magnitude, i.e. going from +0.5 to +1 and going from −0.5 to −1, and “decreasing” refers to decreasing a magnitude, i.e. going from +1 to +0.5 and going from −1 to −0.5. In FIG. 5, in step 80, an electric field is increased to a piezoelectric material within a gate stack, such as by increasing a voltage drop across the piezoelectric material. This may cause a strain in the channel, such as a strain in the z-direction, to increase. For example, assuming the z-direction stress T₃ to be the dominant stress in a zinc oxide piezoelectric layer, when the voltage drop increases, the electric field increases, and the z-direction stress T₃ increases, such as by becoming more tensile or more compressive, which causes a z-direction strain in a channel to increase, such as by becoming more compressive or more tensile, and strains in the x and y-directions in the channel to increase, such as by becoming more tensile or more compressive. In step 82, the electric field is decreased to a piezoelectric material within a gate stack, such as by decreasing a voltage drop across the piezoelectric material. This may cause a strain in the channel, such as a strain in the z-direction, to decrease. For example, again assuming a dominant z-direction stress in a zinc oxide piezoelectric layer, when the voltage drop decreases, the electric field decreases, and the z-direction stress T₃ decreases, such as by becoming less compressive or less tensile, which causes a z-direction strain in a channel to decrease, such as becoming less tensile or less compressive, and strains in the x and y-directions in the channel to decrease, such as by becoming less compressive or less tensile.

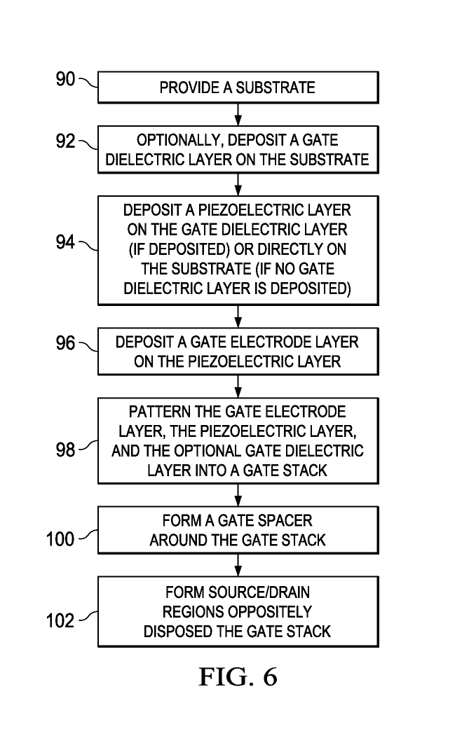

FIG. 6 is a flowchart of a manufacturing process to form the structure of FIG. 1 or 2 according to an embodiment. In step 90, a substrate is provided, such as the substrate 2 in FIG. 1 or 2. In step 92, a gate dielectric layer may optionally be deposited on the substrate, such as by known methods. If the gate dielectric layer is deposited, a structure like FIG. 1 may be obtained, whereas if the gate dielectric layer is not deposited, a structure like FIG. 3 may be obtained. In step 94, a piezoelectric layer is deposited either on the gate dielectric layer or directly on the substrate, depending on whether the gate dielectric layer is deposited. The piezoelectric layer may be deposited, for example, by physical vapor deposition (PVD), chemical vapor deposition (CVD), metal organic CVD (MOCVD), and atomic layer deposition (ALD). The piezoelectric layer may be any of the exemplary materials discussed above with respect to FIGS. 1 and 2. In step 96, a gate electrode layer is deposited on the piezoelectric layer, such as by known methods. The gate electrode layer may be amorphous silicon, polysilicon, metal, metal silicide, metal nitride, combinations thereof, or other known materials. The gate electrode layer may be subsequently processed to form a different material from the material originally formed. For example, one having ordinary skill in the art would understand that polysilicon may be deposited initially, but after the gate stack is formed, a metal may be deposited on the polysilicon gate electrode layer and annealed to form a metal silicide gate electrode layer.

In step 98, the gate electrode layer, the piezoelectric layer, and the optional gate dielectric layer are patterned into a gate stack over the substrate. This may be done by standard lithography techniques known in the art, such as by patterning a resist layer over the area of the gate electrode layer where the gate stack will be formed and subsequently anisotropically etching the layers to form the gate stack. Lightly doped source/drain extensions may then be formed by appropriately doping the substrate. In step 100, a gate spacer is formed along sidewalls of the gate stack. The formation of a gate spacer may include forming a spacer layer, and then patterning the spacer layer to remove its horizontal portions. The deposition may be performed using commonly used techniques. In step 102, source/drain regions are formed disposed on opposite sides of the gate stack. The source/drain regions may be formed by appropriately doping the substrate on opposite sides of the gate stack. This may form a channel region underlying the gate stack disposed between the source/drain regions. The process in FIG. 6 may thus obtain the structure in FIG. 1 if a gate dielectric layer is deposited, or may obtain the structure in FIG. 2 if a gate dielectric layer is not deposited.

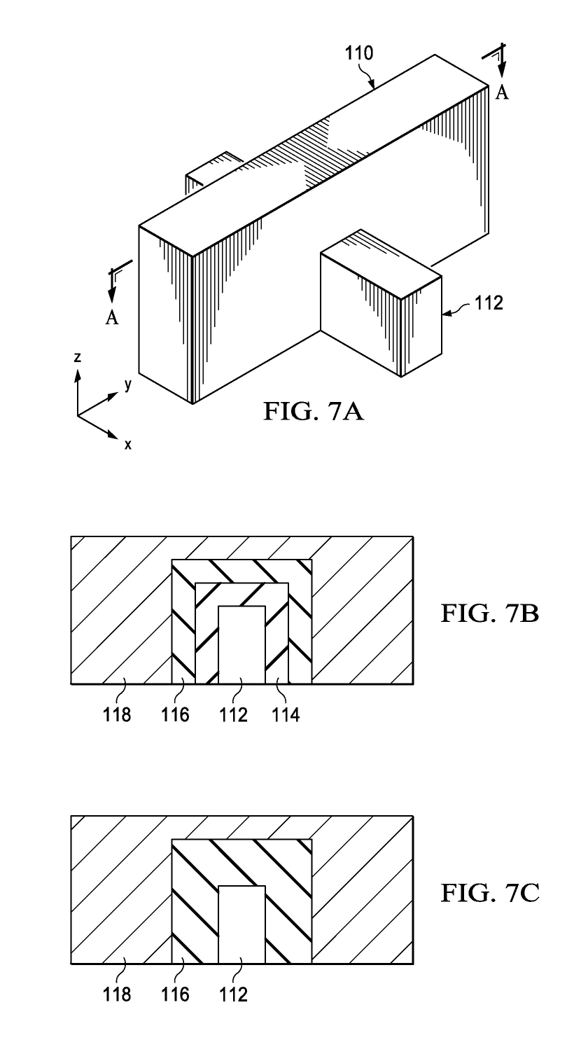

FIG. 7A illustrates a fin field effect transistor (finFET) according to another embodiment. The finFET comprises a gate stack 110 and an active fin 112. FIGS. 7B and 7C depict cross-sections of the finFET gate stack 110 along line A-A, as shown in FIG. 7A. Similar to FIG. 1, FIG. 7B shows a gate stack 110 that comprises a gate dielectric 114, a piezoelectric layer 116, and a gate electrode 118. Similar to FIG. 2, FIG. 7C illustrates a gate stack 110 that comprises a piezoelectric layer 116 and a gate electrode 118 but no separate gate dielectric layer. FIGS. 7B and 7C illustrate the gate stack 110 along three sides of the active fin 112, but embodiments are not limited to such a configuration. For example, the gate stack may be on only two sides of the active fin 112, or may be on four sides of the active fin 112.

The principles discussed above with respect to a planar transistor are similarly applied to the finFET in FIGS. 7A through 7B. However, because the gate electrode 118 and the piezoelectric layer 116 bend at a right angle and extend additionally in the z-direction, the derivation of the electric field and stressor tensor is more complicated. Further, determining the resultant strain in the channel of the active fin 112 may be more complicated because forces are exerted upon the channel from the lateral sidewalls as well as the upper surface.

The process for manufacturing the structures in FIGS. 7A through 7C is similar to the process discussed above with respect to FIG. 6. A person having ordinary skill in the art will readily understand any modifications to that process to obtain the structures in FIGS. 7A through 7C, such as providing a substrate with active fins formed thereon. Accordingly, explicit discussion of such a process is omitted herein.

Although the embodiments and their advantages have been described in detail, it should be understood that various changes, substitutions and alterations can be made herein without departing from the spirit and scope of the disclosure as defined by the appended claims. For example, embodiments contemplate use in p-channel transistors and n-channel transistors. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized. Accordingly, the appended claims are intended to include within their scope such processes, machines, manufacture, compositions of matter, means, methods, or steps.

What is claimed is:

1. A semiconductor device comprising:
a substrate;
an electrode over the substrate; and
a piezoelectric layer disposed between the substrate and the electrode, the piezoelectric layer causing a strain in the substrate when an electric field is generated by the electrode.

2. The semiconductor device of claim 1 further comprising a dielectric layer disposed between the piezoelectric layer and the substrate.

3. The semiconductor device of claim 1, wherein the electrode and piezoelectric layer are components of a gate stack, the gate stack defining a region in the substrate underlying the gate stack in which the strain is caused.

4. The semiconductor device of claim 1, wherein the piezoelectric layer is less than 10 nanometers thick.

5. The semiconductor device of claim 1, wherein the piezoelectric layer has a piezoelectric constant e₃₃ that is positive.

6. The semiconductor device of claim 1, wherein when the electric field generated by the electrode is negative in a first direction orthogonal to a top surface of the substrate, the piezoelectric layer has a tensile stress in the first direction, and the substrate has a compressive strain in the first direction and a biaxial tensile strain in directions parallel to the top surface of the substrate.

7. The semiconductor device of claim 6, wherein when the electrode does not generate the electric field, the piezoelectric layer and the substrate are relaxed.

8. The semiconductor device of claim 1, wherein when the electric field generated by the electrode is positive in a first direction orthogonal to a top surface of the substrate, the piezoelectric layer has a compressive stress in the first direction, and the substrate has a tensile strain in the first direction and a biaxial compressive strain in directions parallel to the top surface of the substrate.

9. The semiconductor device of claim 8, wherein when the electrode does not generate the electric field, the piezoelectric layer and the substrate are relaxed.

10. The semiconductor device of claim 1, wherein the electrode and the piezoelectric layer form a portion of a fin field effect transistor (finFET).

11. A semiconductor device comprising:
a gate stack comprising:
a gate electrode over a substrate; and
a piezoelectric layer between the gate electrode and the substrate; and
source/drain regions oppositely disposed adjacent the gate stack in the substrate, wherein the source/drain regions define a channel region in the substrate underlying the gate stack;
wherein the piezoelectric layer alters a strain in the channel region corresponding to an electric field being altered that is generated by the gate electrode.

12. The semiconductor device of claim 11, wherein the gate stack further comprises a gate dielectric between the piezoelectric layer and the substrate.

13. The semiconductor device of claim 11, wherein a stress in the piezoelectric layer in a direction orthogonal to a top surface of the substrate decreases when the electric field is decreased, which causes a decreased strain parallel to the top surface of the substrate in the channel region.

14. The semiconductor device of claim 11, wherein a stress in the piezoelectric layer in a direction orthogonal to a top surface of the substrate increases when the electric field is increased, which causes an increased strain parallel to the top surface of the substrate in the channel region.

15. The semiconductor device of claim 11, wherein the gate stack and the source/drain regions form a portion of a fin field effect transistor (finFET).

16. A method for forming a semiconductor device comprising:
providing a substrate;
forming a piezoelectric layer over the substrate;
forming an electrode layer over the piezoelectric layer; and
patterning the piezoelectric layer and the electrode layer into a gate stack.

17. The method of claim 16 further comprising forming a dielectric layer over the substrate, wherein the piezoelectric layer is formed over the dielectric layer, and wherein the step of patterning further comprises patterning the dielectric layer.

18. The method of claim 16 further comprising forming source/drain regions oppositely disposed adjacent the gate stack, wherein the gate stack and the source/drain regions define a channel region in the substrate.

19. The method of claim 16, wherein the piezoelectric layer is formed less than 10 nanometers thick.

20. The method of claim 16, wherein the piezoelectric layer comprises a material selected from the group consisting essentially of zinc oxide (ZnO), lithium niobate (LiNbO₃), lithium tantalate (LiTaO₃), and combinations thereof.
